(19) United States
(12) Patent Application Publication
(10) Pub. No.: US 2025/0344313 A1
(43) Pub. Date: Nov. 6, 2025

(54) CHIPSET ASSEMBLY WITH ANTI-TILT MECHANISM AND ASSEMBLING METHOD THEREOF

(71) Applicant: Wiwynn Corporation, New Taipei City (TW)

(72) Inventors: Ping-Sheng Yeh, New Taipei City (TW); Yen-Hsiang Wang, New Taipei City (TW); Wei-Chen Lin, New Taipei City (TW); Yi-Shen Chen, New Taipei City (TW)

(73) Assignee: Wiwynn Corporation, New Taipei City (TW)

(21) Appl. No.: 19/192,311

(22) Filed: Apr. 28, 2025

Related U.S. Application Data
(60) Provisional application No. 63/641,414, filed on May 1, 2024.

(30) Foreign Application Priority Data
Feb. 3, 2025 (TW) 114103793

(51) Int. Cl. H05K 1/02

(52) U.S. Cl. CPC H05K 1/0203

(57) ABSTRACT

A chipset assembly includes a circuit board, a chip, a bracket, a heat dissipating member, a plurality of elastic members and an operating member. The chip is disposed on the circuit board. The bracket is disposed on the circuit board and around the chip. The heat dissipating member is disposed above the chip. The elastic members are located between the bracket and the heat dissipating member. The operating member is movably disposed at a side of the bracket. When the operating member is located at an unlock position, the elastic members support the heat dissipating member, such that the heat dissipating member is separated from the chip. When the operating member moves from the unlock position to a lock position, the operating member drives the heat dissipating member to move toward the chip, such that the heat dissipating member compresses the elastic members and contacts the chip.

### CROSS REFERENCE TO RELATED APPLICATIONS

This application claims the benefit of U.S. Provisional Application No. 63/641, 414, filed on May 1, 2024. The content of the application is incorporated herein by reference.

### BACKGROUND OF THE INVENTION

### 1. Field of the Invention

The invention relates to a chipset assembly and, more particularly, to a chipset assembly with an anti-tilt mechanism and an assembling method thereof.

### 2. Description of the Prior Art

As the performance of a chip increases, more and more heat is generated when the chip operates. Thus, heat dissipation is extremely important for the chip. At present, a heat sink is assembled on the chip by screws. If the heat sink is tilted during assembly and contacts the chip unevenly, the chip (especially a bare die) may be damaged due to excessive local pressure.

### SUMMARY OF THE INVENTION

Therefore, an objective of the invention is to provide a chipset assembly with an anti-tilt mechanism and an assembling method thereof, which can prevent a chip from being damaged during assembly.

According to an embodiment of the invention, a chipset assembly comprises a circuit board, a chip, a bracket, a heat dissipating member, a plurality of elastic members and an operating member. The chip is disposed on the circuit board. The bracket is disposed on the circuit board and around the chip. The heat dissipating member is disposed above the chip. The plurality of elastic members are located between the bracket and the heat dissipating member. The operating member is movably disposed at a side of the bracket. When the operating member is located at an unlock position, the plurality of elastic members support the heat dissipating member, such that the heat dissipating member is separated from the chip. When the operating member moves from the unlock position to a lock position, the operating member drives the heat dissipating member to move toward the chip, such that the heat dissipating member compresses the plurality of elastic members and contacts the chip.

According to an embodiment of the invention, an assembling method of a chipset assembly comprises steps of disposing a chip on a circuit board; disposing a bracket around the chip on the circuit board, wherein an operating member is movably disposed at a side of the bracket; disposing a heat dissipating member above the chip, wherein a plurality of elastic members are located between the bracket and the heat dissipating member, and the plurality of elastic members support the heat dissipating member, such that the heat dissipating member is separated from the chip; and moving the operating member from an unlock position to a lock position to drive the heat dissipating member to move toward the chip, such that the heat dissipating member compresses the plurality of elastic members and contacts the chip.

The chipset assembly and the assembling method thereof of the invention have the following characteristics: 1) by supporting the heat dissipating member with the elastic members, the heat dissipating member is prevented from contacting the chip before assembly, and the tilt of the heat dissipating member or uneven pressure distribution during assembly can be reduced; 2) by applying downward pressure through the operating member and combining with the elastic members, the heat dissipating member is ensured to contact the chip without tilting; and 3) by using the screws and the nuts to fix the bracket, the circuit board and the back plate together, the structural support strength and stability of the chipset assembly can be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded view illustrating a chipset assembly according to an embodiment of the invention.

FIG. 2 is an isometric view illustrating the operating member shown in FIG. 1.

FIG. 3 is a partial exploded view illustrating the chipset assembly shown in FIG. 1.

FIG. 4 is an isometric view illustrating the operating member located at an unlock position.

FIG. 5 is a front view illustrating the chipset assembly shown in FIG. 4.

FIG. 6 is a side view illustrating the chipset assembly shown in FIG. 4.

FIG. 7 is an isometric view illustrating the operating member shown in FIG. 4 moving to a lock position.

FIG. 8 is a side view illustrating the chipset assembly shown in FIG. 7.

FIG. 9 is a top view illustrating the chipset assembly shown in FIG. 7.

FIG. 10 is a flowchart illustrating an assembling method of the chipset assembly according to an embodiment of the invention.

### DETAILED DESCRIPTION

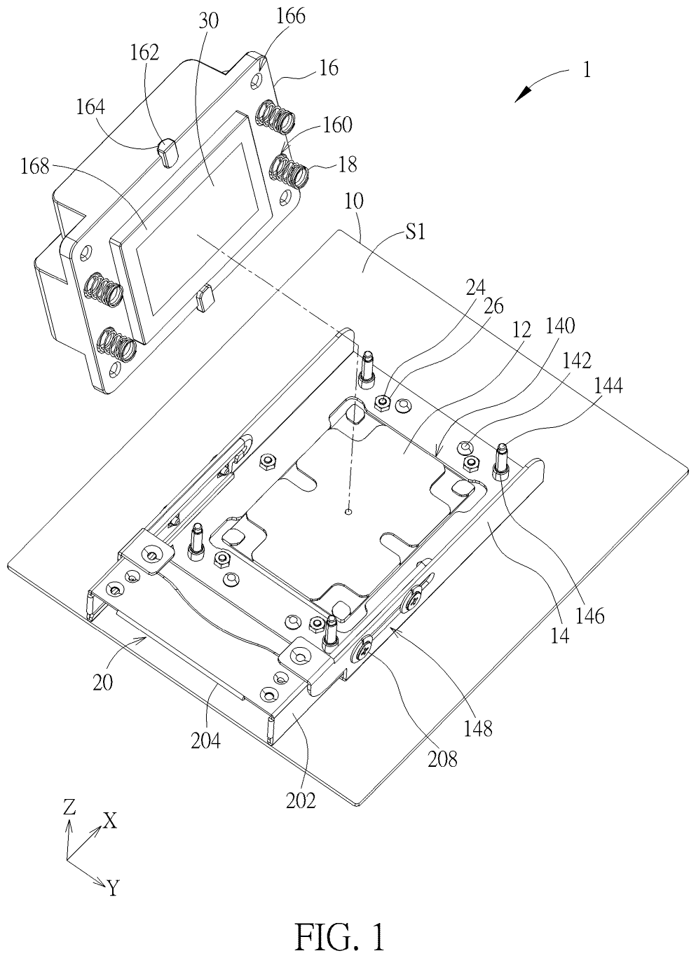

Referring to FIG. 1, which is an exploded view illustrating a chipset assembly 1 according to an embodiment of the invention. The chipset assembly 1 comprises a circuit board 10, a chip 12, a bracket 14, a heat dissipating member 16, a plurality of elastic members 18 and an operating member 20. An anti-tilt mechanism of the chipset assembly 1 may essentially consist of the bracket 14, the heat dissipating member 16, the elastic members 18 and the operating member 20.

The chip 12 is disposed on the circuit board 10. In this embodiment, the chip 12 may be a bare die fixed on the circuit board 10 and the chip 12 may be any type of integrated circuit, such as microprocessor, general-purpose processor, application specific integrated circuit (ASIC), random access memory (RAM), power integrated circuit, etc., but the invention is not so limited. The bracket 14 is disposed on the circuit board 10 and around the chip 12. In this embodiment, the bracket 14 may have a hollow region 140. When the bracket 14 is disposed on the circuit board 10, the chip 12 is located in the hollow region 140, such that the bracket 14 is around the chip 12.

The heat dissipating member 16 is disposed above the chip 12 and the elastic members 18 are located between the bracket 14 and the heat dissipating member 16. In this embodiment, the heat dissipating member 16 may be, for example, a cold plate, a heat pipe, a heat sink, or a combination thereof, and the elastic member 18 may be, for example, a spring. In this embodiment, the elastic members 18 may be fixed to the heat dissipating member 16 and adjacent to two sides of the heat dissipating member 16 parallel to a Y direction. For example, the bottom surface of the two sides of the heat dissipating member 16 parallel to the Y direction may be formed with a plurality of recesses 160 for accommodating and fixing the elastic members 18. Furthermore, the bracket 14 may have a plurality of protrusions 142 at positions corresponding to the plurality of recesses 160. When the heat dissipating member 16 is disposed above the chip 12, an end of the elastic member 18 is sleeved on the protrusion 142 to position the elastic member 18 on the bracket 14. At this time, the elastic members 18 are located between the bracket 14 and the heat dissipating member 16. In another embodiment, the elastic members 18 may also be fixed to the bracket 14. When the heat dissipating member 16 is disposed above the chip 12, an end of the elastic member 18 abuts against the bottom surface of the heat dissipating member 16, such that the elastic members 18 are located between the bracket 14 and the heat dissipating member 16. It should be noted that the number of elastic members 18 may be determined according to practical applications, so the invention is not limited to the embodiment shown in the figure. Furthermore, two sides of the heat dissipating member 16 have two protruding portions 162, wherein the two protruding portions 162 are located at a middle of two sides of the heat dissipating member 16 parallel to an X direction. Each of the two protruding portions 162 is formed with an inclined surface 164.

The bracket 14 comprises a plurality of positioning pins 144 and the heat dissipating member 16 is formed with a plurality of positioning holes 166. When the heat dissipating member 16 is disposed above the chip 12, the positioning pins 144 are inserted into the positioning holes 166 to position the heat dissipating member 16 above the chip 12. Each of the positioning pins 144 has a stop surface 146, wherein the stop surface 146 is higher than the chip 12 in a Z direction. The stop surface 146 is configured to restrain a moving distance of the heat dissipating member 16 toward the chip 12 to prevent the heat dissipating member 16 from crushing the chip 12. It should be noted that the numbers of positioning pins 144 and positioning holes 166 may be determined according to practical applications, so the invention is not limited to the embodiment shown in the figure.

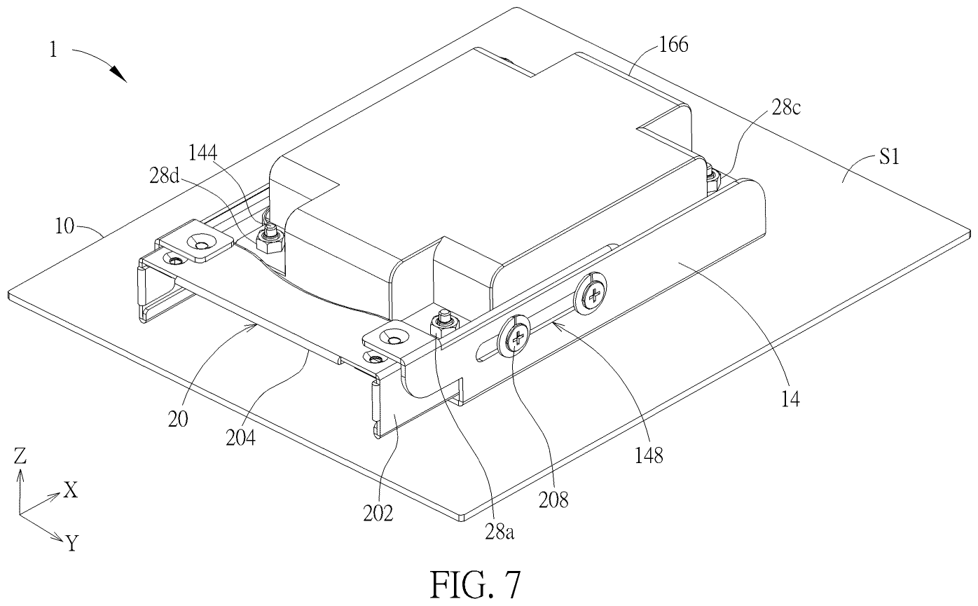

The operating member 20 is movably disposed at a side of the bracket 14. In this embodiment, the operating member 20 may move between an unlock position shown in FIG. 1 and a lock position shown in FIG. 7.

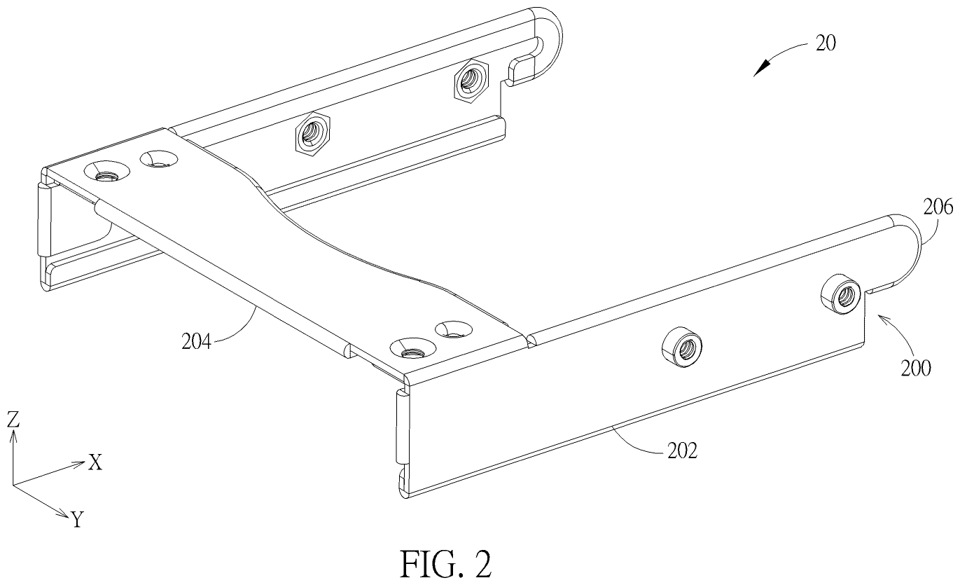

Referring to FIG. 2, which is an isometric view illustrating the operating member 20 shown in FIG. 1. Two sides of the operating member 20 are formed with two engaging recesses 200, and the operating member 20 comprises two arms 202 and a handle 204, wherein the two engaging recesses 200 are formed at ends of the two arms 202. The two arms 202 extend along the X direction, the handle 204 extends along the Y direction, and two ends of the handle 204 are connected to another ends of the two arms 202. Furthermore, an end of each of the two arms 202 is formed with a half arc 206. In this embodiment, two sides of the bracket 14 may be formed with two guiding grooves 148 (shown in FIG. 1) extending along the X direction, and each of the two arms 202 may comprise a guiding portion 208. The guiding portion 208 is movably disposed in the guiding groove 148, such that the operating member 20 may move with respect to the bracket 14 along the guiding groove 148. In practical applications, the guiding portion 208 may be, but is not limited to, a screw fixed to the arm 202. It should be noted that the number of guiding portions 208 of each arm 202 may be one or more according to practical applications.

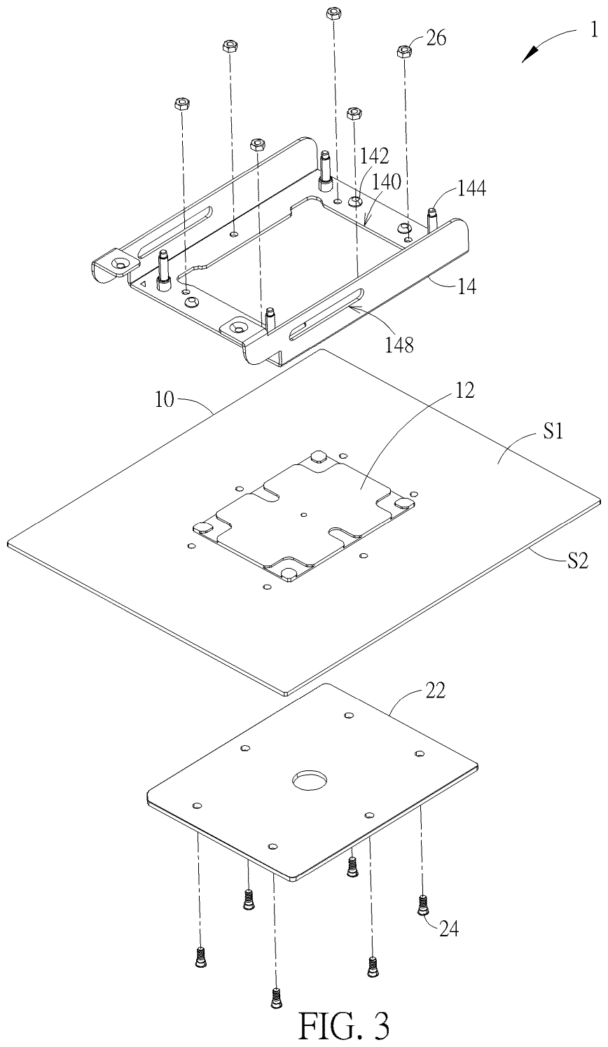

Referring to FIG. 3, which is a partial exploded view illustrating the chipset assembly 1 shown in FIG. 1. The chipset assembly 1 may further comprise a back plate 22, a plurality of screws 24 and a plurality of nuts 26. In this embodiment, the bracket 14 is disposed on an upper surface S1 of the circuit board 10 and the back plate 22 is disposed on a lower surface S2 of the circuit board 10. The screws 24 sequentially pass through the back plate 22, the circuit board 10 and the bracket 14 from the lower surface S2 of the circuit board 10, and the nuts 26 are fixed to the screws 22 from the upper surface S1 of the circuit board 10, such that the circuit board 10 is sandwiched between the bracket 14 and the back plate 22. By using the screws 24 and the nuts 26 to fix the bracket 14, the circuit board 10 and the back plate 22 together, the structural support strength and stability of the chipset assembly 1 can be enhanced. In practical applications, the bracket 14, the circuit board 10 and the back plate 22 may be formed with a plurality of through holes for the screws 24 to pass through. It should be notes that the numbers of screws 24 and nuts 26 may be determined according to practical applications, so the invention is not limited to the embodiment shown in the figure.

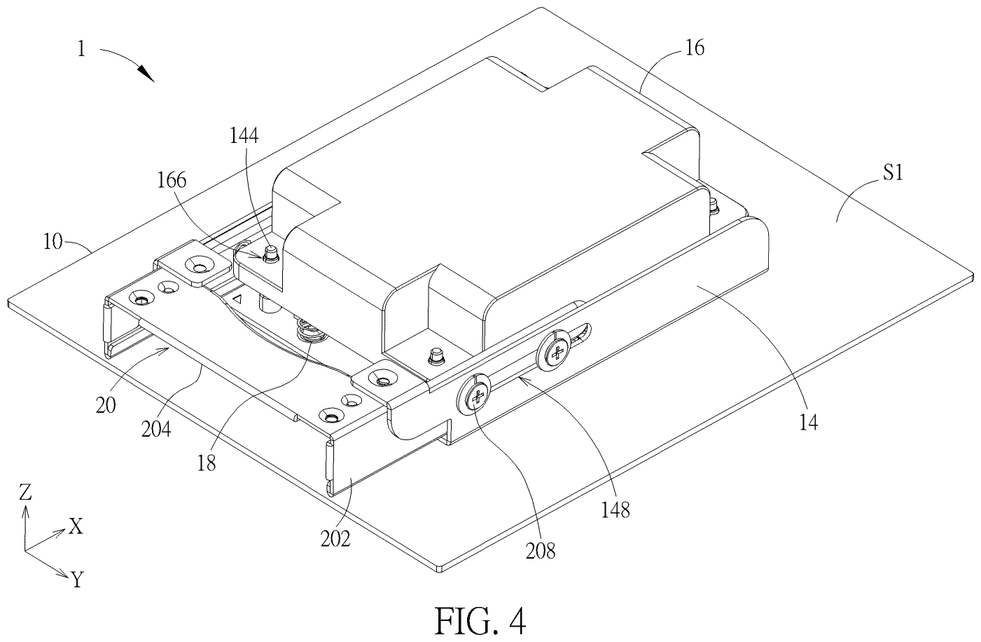

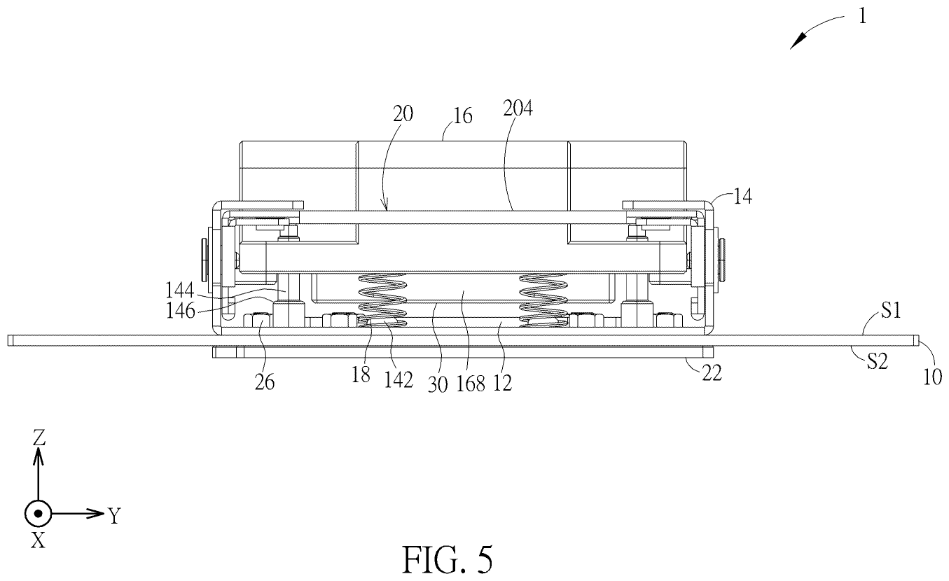

Referring to FIGS. 4 and 5, FIG. 4 is an isometric view illustrating the operating member 20 located at an unlock position, and FIG. 5 is a front view illustrating the chipset assembly 1 shown in FIG. 4. When the operating member 20 is located at the unlock position, the elastic members 18 support the heat dissipating member 16, such that the heat dissipating member 16 is separated from the chip 12, i.e. the heat dissipating member 16 does not contact the chip 12.

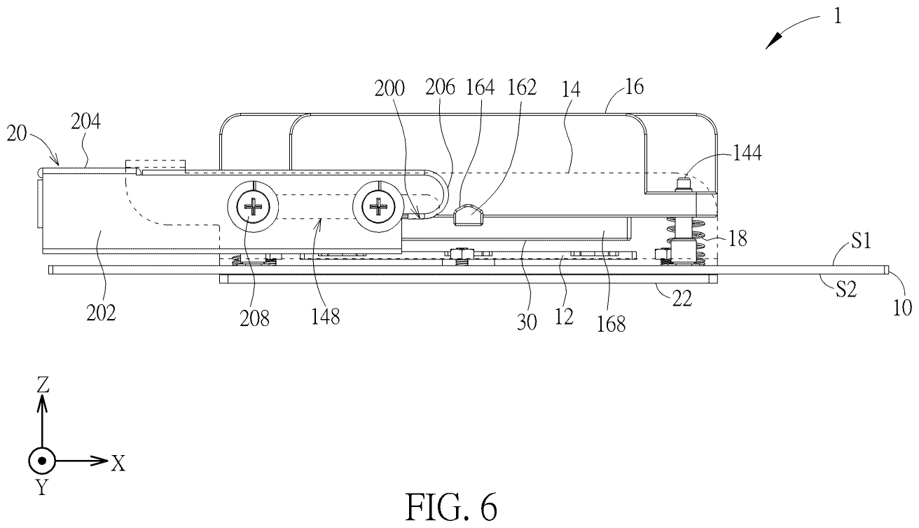

Referring to FIG. 6, which is a side view illustrating the chipset assembly 1 shown in FIG. 4. When the operating member 20 is located at the unlock position, the inclined surface 164 of the protruding portion 162 faces the half arc 206 of the operating member 20, and the protruding portion 162 is higher than the engaging recess 200 in the Z direction.

Referring to FIG. 7, which is an isometric view illustrating the operating member 20 shown in FIG. 4 moving to a lock position. After the heat dissipating member 16 has been disposed above the chip 12, a user may push the handle 204 of the operating member 20 along the X direction, such that the operating member 20 moves from the unlock position shown in FIG. 1 to the lock position shown in FIG. 7.

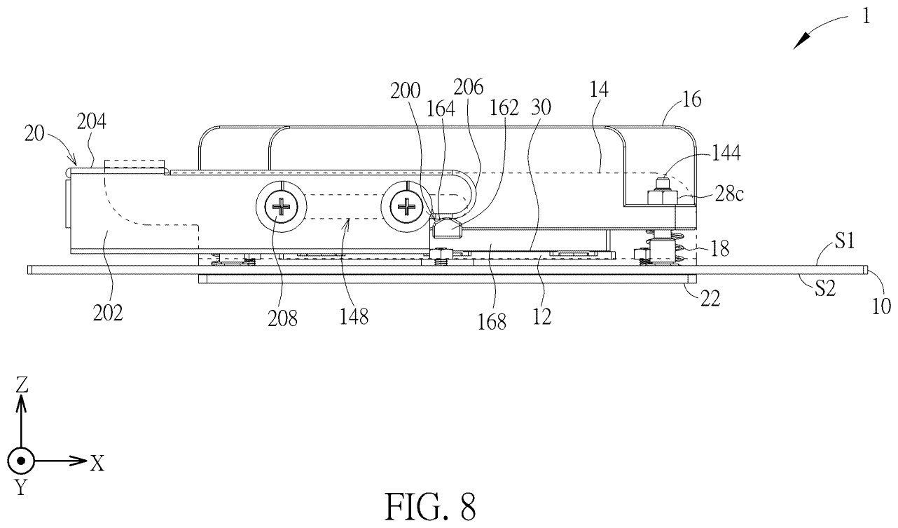

Referring to FIG. 8, which is a side view illustrating the chipset assembly 1 shown in FIG. 7. When the operating member 20 moves from the unlock position shown in FIG. 6 to the lock position shown in FIG. 8, the operating member 20 drives the heat dissipating member 16 to move toward the chip 12, such that the heat dissipating member 16 compresses the elastic members 18 and contacts the chip 12. For further explanation, when the operating member 20 moves from the unlock position shown in FIG. 6 to the lock position shown in FIG. 8, the half arc 206 of the operating member 20 abuts against the inclined surface 164 of the heat dissipating member 16, such that the two arms 202 presses the two protruding portions 162 of the heat dissipating member 16 downward along the Z direction to drive the heat dissipating member 16 to move toward the chip 12 along the Z direction. After the operating member 20 has moved to the lock position shown in FIG. 8, the two protruding portions 162 of the heat dissipating member 16 engage with the two engaging recesses 200 of the operating member 20, and the protruding portion 162 is lower than the engaging recess 200 in the Z direction. At this time, the elastic members 18 cannot push the heat dissipating member 16 upward, such that the heat dissipating member 16 keeps contacting the chip 12. On the other hand, when the operating member 20 moves from the lock position shown in FIG. 8 to the unlock position shown in FIG. 6, the compressed elastic members 18 drive the heat dissipating member 16 to move away from the chip 12, such that the heat dissipating member 16 is separated from the chip 12.

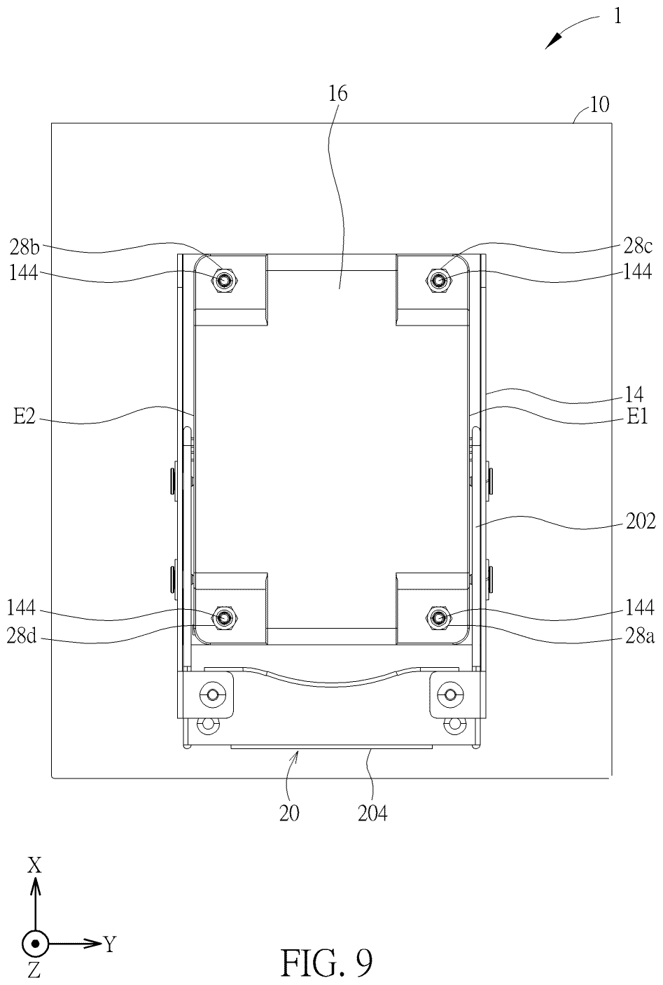

Referring to FIG. 9, which is a top view illustrating the chipset assembly 1 shown in FIG. 7. After the operating member 20 has moved to the lock position shown in FIG. 9, the user may sequentially fix a plurality of nuts 28a, 28b, 28c, 28d to the plurality of positioning pins 144 of the bracket 14 to fix the heat dissipating member 16. For example, a (2n-1)th nut of the nuts 28a, 28b, 28c, 28d may be fixed to a first side E1 of the heat dissipating member 16 parallel to the X direction, a 2n-th nut of the nuts 28a, 28b, 28c, 28d may be fixed to a second side E2 of the heat dissipating member 16 parallel to the X direction, and n is a positive integer. As shown in FIG. 9, the user may first fix the first nut 28a to the lower right corner of the first side E1 of the heat dissipating member 16. Then, the user may fix the second nut 28b to the upper left corner of the second side E2 of the heat dissipating member 16. Then, the user may fix the third nut 28c to the upper right corner of the first side E1 of the heat dissipating member 16. Finally, the user may fix the fourth nut 28d to the lower left corner of the second side E2 of the heat dissipating member 16. That is to say, the odd-numbered nuts 28a, 28c may be fixed to the first side E1 of the heat dissipating member 16, and the even-numbered nuts 28b, 28d may be fixed to the second side E2 of the heat dissipating member 16. During the process of fixing the nuts 28a, 28b, 28c, 28d, the heat dissipating member 16 is supported by the elastic members 18. Therefore, the nuts 28a, 28b, 28c, 28d may be fixed at one time respectively without the need for segmental fixation.

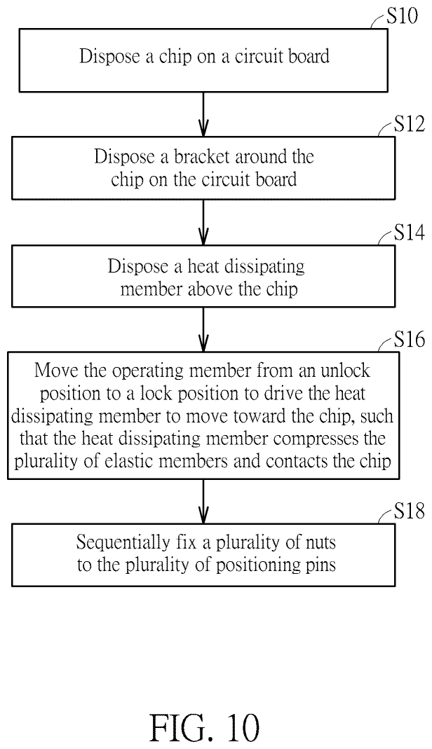

Referring to FIG. 10, which is a flowchart illustrating an assembling method of the chipset assembly 1 according to an embodiment of the invention. The assembling method of the chipset assembly 1 is depicted below using the components shown in FIGS. 1 to 9 along with FIG. 10. When assembling chipset assembly 1, first, step S10 is performed to dispose a chip 12 on a circuit board 10 (as shown in FIG. 3). Then, step S12 is performed to dispose a bracket 14 around the chip 12 on the circuit board 10 (as shown in FIG. 1). In this embodiment, step S12 may dispose the bracket 14 on an upper surface S1 of the circuit board 10 and dispose a back plate 22 on a lower surface S2 of the circuit board 10. Then, step S12 may sequentially pass a plurality of screws 24 through the back plate 22, the circuit board 16 and the bracket 14 from the lower surface S2 of the circuit board 10 and then fix a plurality of nuts 26 to the screws 24 from the upper surface S1 of the circuit board 10 (as shown in FIG. 3).

Then, step S14 is performed to dispose a heat dissipating member 16 above the chip 12 (as shown in FIGS. 4 to 6). In this embodiment, step S14 may insert the positioning pins 144 of the bracket 14 into the positioning holes 166 of the heat dissipating member 16 to position the heat dissipating member 16 above the chip 12. Before step S14, the assembling method may fix the elastic members 18 to the heat dissipating member 16 or the bracket 14 in advance. In this embodiment, the elastic members 18 may be fixed to the heat dissipating member 16 (as shown in FIG. 1). Thus, after disposing the heat dissipating member 16 above the chip 12, the elastic members 18 are located between the bracket 14 and the heat dissipating member 16. Furthermore, after step S10 and before step S14, the assembling method may dispose a heat dissipating pad 30 (as shown in FIG. 1) above the chip 12, such that the heat dissipating member 16 contacts the chip 12 through the heat dissipating pad 30. In this embodiment, the heat dissipating pad 30 may be attached to a base 168 of the heat dissipating member 16 (as shown in FIG. 1), but the invention is not so limited. The heat dissipating pad 30 disposed between the chip 12 and the heat dissipating member 16 may increase the pressure therebetween, such that the heat generated by the chip 12 may be quickly conducted to the heat dissipating member 16 through the heat dissipating pad 30 to improve heat dissipating efficiency.

Then, step S16 is performed to move the operating member 20 from an unlock position to a lock position to drive the heat dissipating member 16 to move toward the chip 12, such that the heat dissipating member 16 compresses the elastic members 18 and contacts the chip 12 (as shown in FIGS. 7 and 8). In this embodiment, step S16 pushes the handle 204 of the operating member 20 along an X direction, such that the two arms 202 presses the two protruding portions 162 of the heat dissipating member 16 downward along a Z direction to drive the heat dissipating member 16 to move toward the chip 12 along the Z direction.

Then, step S18 is performed to sequentially fixing the plurality of nuts 28a, 28b, 28c, 28d to the plurality of positioning pins 144 of the bracket 14 (as shown in FIG. 9) to fix the heat dissipating member 16. Accordingly, the assembly of the chipset assembly 1 is completed. It should be noted that the sequence of fixing the nuts 28a, 28b, 28c, 28d is mentioned in the above and will not be repeated herein.

As mentioned in the above, the chipset assembly of the invention utilizes the elastic members to support the heat dissipating member, such that the heat dissipating member is prevented from contacting the chip before assembly, and the tilt of the heat dissipating member or uneven pressure distribution during assembly can be reduced. Furthermore, by applying downward pressure through the operating member and combining with the elastic members, the heat dissipating member is ensured to contact the chip without tilting. Moreover, by using the screws and the nuts to fix the bracket, the circuit board and the back plate together, the structural support strength and stability of the chipset assembly can be enhanced. Therefore, the invention can effectively improve the assembly efficiency of the chipset assembly and ensure the product quality of the chipset assembly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chipset assembly comprising:
a circuit board;
a chip disposed on the circuit board;
a bracket disposed on the circuit board and around the chip;
a heat dissipating member disposed above the chip;
a plurality of elastic members located between the bracket and the heat dissipating member; and
an operating member movably disposed at a side of the bracket;
wherein, when the operating member is located at an unlock position, the plurality of elastic members support the heat dissipating member, such that the heat dissipating member is separated from the chip;
wherein, when the operating member moves from the unlock position to a lock position, the operating member drives the heat dissipating member to move toward the chip, such that the heat dissipating member compresses the plurality of elastic members and contacts the chip.

2. The chipset assembly of claim 1, wherein two sides of the heat dissipating member have two protruding portions, two sides of the operating member are formed with two engaging recesses; wherein, when the operating member moves from the unlock position to the lock position, the operating member presses the two protruding portions downward, such that the heat dissipating member moves toward the chip and the two protruding portions engage with the two engaging recesses.

3. The chipset assembly of claim 2, wherein the two protruding portions are located at a middle of two sides of the heat dissipating member parallel to an X direction.

4. The chipset assembly of claim 2, wherein the operating member comprises:
two arms extending along an X direction, the two engaging recesses being formed at ends of the two arms; and
a handle extending along a Y direction, two ends of the handle being connected to another ends of the two arms.

5. The chipset assembly of claim 4, wherein each of the two protruding portions is formed with an inclined surface, an end of each of the two arms is formed with a half arc, and the inclined surface faces the half arc.

6. The chipset assembly of claim 4, wherein two sides of the bracket are formed with two guiding grooves extending along the X direction, each of the two arms comprises a guiding portion, and the guiding portion is disposed in the guiding groove.

7. The chipset assembly of claim 1, wherein the bracket comprises a plurality of positioning pins, the heat dissipating member is formed with a plurality of positioning holes, and the plurality of positioning pins are inserted into the plurality of positioning holes to position the heat dissipating member above the chip.

8. The chipset assembly of claim 7, wherein each of the plurality of positioning pins has a stop surface, and the stop surface is higher than the chip in a Z direction.

9. The chipset assembly of claim 1, further comprising a back plate, a plurality of screws and a plurality of nuts, wherein the bracket is disposed on an upper surface of the circuit board, the back plate is disposed on a lower surface of the circuit board, the plurality of screws sequentially pass through the back plate, the circuit board and the bracket from the lower surface of the circuit board, and the plurality of nuts are fixed to the plurality of screws from the upper surface of the circuit board.

10. The chipset assembly of claim 1, wherein the plurality of elastic members are fixed to the heat dissipating member or the bracket, and adjacent to two sides of the heat dissipating member parallel to a Y direction.

11. An assembling method of a chipset assembly comprising steps of:
disposing a chip on a circuit board;
disposing a bracket around the chip on the circuit board, wherein an operating member is movably disposed at a side of the bracket;
disposing a heat dissipating member above the chip, wherein a plurality of elastic members are located between the bracket and the heat dissipating member, and the plurality of elastic members support the heat dissipating member, such that the heat dissipating member is separated from the chip; and
moving the operating member from an unlock position to a lock position to drive the heat dissipating member to move toward the chip, such that the heat dissipating member compresses the plurality of elastic members and contacts the chip.

12. The assembling method of claim 11, wherein two sides of the heat dissipating member have two protruding portions, two sides of the operating member are formed with two engaging recesses; wherein, when the operating member moves from the unlock position to the lock position, the operating member presses the two protruding portions downward, such that the heat dissipating member moves toward the chip and the two protruding portions engage with the two engaging recesses.

13. The assembling method of claim 12, wherein the operating member has a handle and two arms, the two arms are connected to two sides of the handle, the two engaging recesses are formed at ends of the two arms; wherein the step of moving the operating member from the unlock position to the lock position further comprises step of:
pushing the handle along an X direction, such that the two arms presses the two protruding portions downward along a Z direction to drive the heat dissipating member to move toward the chip along the Z direction.

14. The assembling method of claim 11, wherein before the step of disposing the heat dissipating member above the chip, the assembling method further comprises step of:
fixing the plurality of elastic members to the heat dissipating member or the bracket, wherein the plurality of elastic members are adjacent to two sides of the heat dissipating member parallel to a Y direction.

15. The assembling method of claim 11, wherein after the step of disposing the chip on the circuit board and before the step of disposing the heat dissipating member above the chip, the assembling method further comprises step of:
disposing a heat dissipating pad above the chip, wherein the heat dissipating member contacts the chip through the heat dissipating pad.

16. The assembling method of claim 11, wherein the bracket comprises a plurality of positioning pins, the heat dissipating member is formed with a plurality of positioning holes, and the step of disposing the heat dissipating member above the chip further comprises step of:
inserting the plurality of positioning pins into the plurality of positioning holes to position the heat dissipating member above the chip.

17. The assembling method of claim 16, further comprising steps of:
sequentially fixing a plurality of nuts to the plurality of positioning pins;
wherein a (2n-1)th nut of the plurality of nuts is fixed to a first side of the heat dissipating member parallel to an X direction, a 2n-th nut of the plurality of nuts is fixed to a second side of the heat dissipating member parallel to the X direction, and n is a positive integer.

18. The assembling method of claim 11, further comprising steps of:
disposing the bracket on an upper surface of the circuit board;
disposing a back plate on a lower surface of the circuit board;
sequentially passing a plurality of screws through the back plate, the circuit board and the bracket from the lower surface of the circuit board; and
fixing a plurality of nuts to the plurality of screws from the upper surface of the circuit board.
